(19) United States
(12) Patent Application Publication
(10) Pub. No.: US 2004/0212384 A1
(43) Pub. Date: Oct. 28, 2004

(54) TEST APPARATUS FOR A PRINTED-CIRCUIT BOARD

(75) Inventor: Arnulf Maag, Alsdorf (DE)

Correspondence Address: THE FIRM OF KARL F ROSS, 5676 RIVERDALE AVENUE, PO BOX 900, RIVERDALE (BRONX), NY, 10471-0900, US

(73) Assignee: ELCO Europe GmbH

(21) Appl. No.: 10/445,556

(22) Filed: May 27, 2003

(30) Foreign Application Priority Data
May 29, 2002 (DE) 10223867.7

(51) Int. Cl. G01R 31/02

(52) U.S. Cl. 324/761; 324/758

(57) ABSTRACT

An apparatus for testing a printed-circuit board has sensor pins formed by contiguous zones each having a predetermined number of the sensor pins and respective spring strips juxtaposed with the zones and each having the predetermined number of contacts each formed with a socket for a respective one of the pins of the respective zone. Respective main printed-circuit boards juxtaposed with the spring strips each have oppositely directed first and second sides and each also have an end region formed with an array of the predetermined number of contact points. Respective first and second side boards flanking the first and second faces of each of the end regions each have contact points each connected to a respective spring-strip contact. Respective first and second arrays of press-in pins are engaged through the respective first and second side boards with the contact points of the respective faces of the respective main boards.

### FIELD OF THE INVENTION

The present invention relates to printed-circuit test apparatus. More particularly this invention concerns an apparatus for testing printed-circuit boards.

### BACKGROUND OF THE INVENTION

In the manufacture of printed-circuit boards it is essential that the myriad complexly routed conductive traces on a board all be perfect, that is none can be interrupted or shorted out with another. It is therefore necessary to test a board after it is printed or etched in order to determine if it is usable.

This is done in an apparatus of the type generally discussed in U.S. Pat. No. 4,674,006 (reissued as RE 34,491) and U.S. Pat. No. 6,191,597 of H. Driller as well as German 81 31 861 and 31 10 056. It has an array of as many as several thousand contacts that are pressed against a face of the circuit board. Then a computer connected to all of these contacts energizes them one at a time with an electrical voltage and the computer notes with each such energization what other contacts show the voltage, that is are connected to the energized contact. This test is run for a faultless master circuit board and then for the boards to be tested. Any board whose results do not perfectly match those of the faultless master board is culled out.

The test pins must be extremely closely spaced in order to test the traces of modern-day printed-circuit boards which are very densely packed and separated by tiny gaps. In addition each test pin must be individually connected to the circuitry of the test apparatus. So as to make the testing apparatus adaptable to boards of different sizes and to allow replacement of defective pins, it is therefore standard to subdivide the array of pins into numerous zones that each comprise as few as eight or sixteen pins themselves connected to an input of a respective evaluating circuit in turn connected to the test apparatus.

Each such evaluating circuit for a particular zone has a main board that has a connection region in turn connected to the respective sensor pins. This connection is made by a side plate connected via an adapter to the pins of the test apparatus that actually engage the board being tested.

The main boards carrying the modular evaluating circuits can be set up to each handle, typically, 128 connections. The board itself has a certain minimum size, but in recent times the density of the traces on standard printed-circuit boards has become so small that testing them is very difficult. There simply is not enough room to align the 128 contacts of the board with the densely packed sensor pins.

### OBJECTS OF THE INVENTION

It is therefore an object of the present invention to provide an improved apparatus for testing printed-circuit boards.

Another object is the provision of such an improved apparatus for testing printed-circuit boards which overcomes the above-given disadvantages, that is which allows conventional evaluating-circuit boards to be connected to very closely spaced sensor pins.

### SUMMARY OF THE INVENTION

An apparatus for testing a printed-circuit board has according to the invention an array of closely spaced sensor pins formed by a plurality of contiguous zones each having a predetermined number of the sensor pins and respective spring strips juxtaposed with the zones and each having the predetermined number of contacts each formed with a socket for a respective one of the pins of the respective zone. Respective main printed-circuit boards juxtaposed with the spring strips each have oppositely directed first and second sides and each also have an end region formed with an array of the predetermined number of contact points. Respective first and second side boards flanking the first and second faces of each of the end regions each have contact points each connected to a respective one of the spring-strip contacts. Respective first and second arrays of press-in pins are engaged through the respective first and second side boards with the contact points of the respective faces of the respective main boards.

Thus with this system if the main board has, for example, sixteen rows of eight contact points for a total of 128 contact points, it is possible for each of them to be connected to a respective pin over a distance equal to the distance occupied by the sixteen rows. This is accomplished by, in effect, using two side plates so contact points on both sides of the contact region can be connected to respective traces of the side boards that lead to respective spring-strip contacts. The result is extremely closely packed sensor pins in a system using conventionally spaced contact points on conventional evaluating-circuit main boards.

According to the invention each array of press-in pins has half the predetermined number of press-in pins. Furthermore the side-board contact points are arranged in rows set at a predetermined spacing equal to generally twice a spacing between adjacent sensor pins.

The test apparatus further has according to the invention respective outer insulating plates lying against outer faces of the side boards. The press-in pins have heads bearing on the outer insulating plates and projecting through the respective outer insulating plates to where they contact the respective contact points. Each outer insulating plate is further formed with counterbores receiving the heads of the respective press-in pins. The outer insulating plates are connected to rails holding the respective main board. Thus a relative thin main board, often less than 1 mm thick, is reinforced by these rails.

Similarly according to this invention respective inner insulating plates are provided between the side boards and the respective faces of the main boards. The press-in pins pass through the inner insulating plates.

The first press-in pins according to the invention are seated in the respective first side boards and are substantially out of contact with the respective second side boards and the second press-in pins are seated in the respective second side boards and are substantially out of contact with the respective first side boards. The main-board contact points are formed as throughgoing conductively lined holes which may be fitted with socket contacts to connect the traces of the main board to the traces of the side boards via the respective press-in pins.

The side boards according to the invention thus have conductive traces connecting the respective side-board contact points with the respective spring-strip contacts. The spring-strip contacts are soldered to the respective traces. These spring-strip contacts are stamped of sheet metal.

### BRIEF DESCRIPTION OF THE DRAWING

The above and other objects, features, and advantages will become more readily apparent from the following description, reference being made to the accompanying drawing in which:

FIG. 1 is a large-scale top view of a portion of a testing apparatus according to the invention;

FIG. 2 is a section taken along line II-II of FIG. 1;

FIG. 3 is a large-scale view of a detail of FIG. 2;

FIG. 4 is a view of a blank from which a contact in accordance with the invention is made; and

FIG. 5 is a large-scale view of another detail of FIG. 2.

### SPECIFIC DESCRIPTION

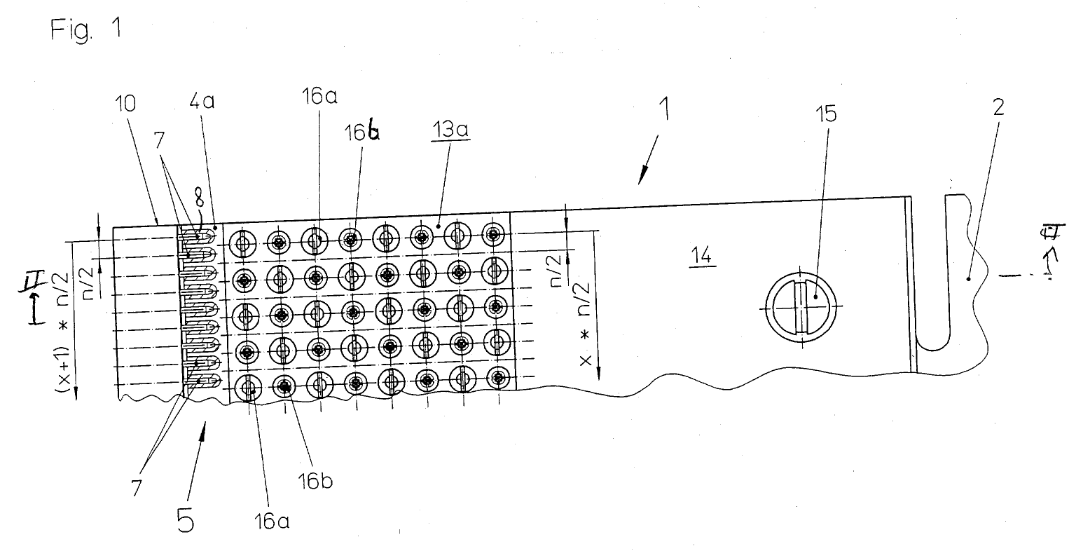

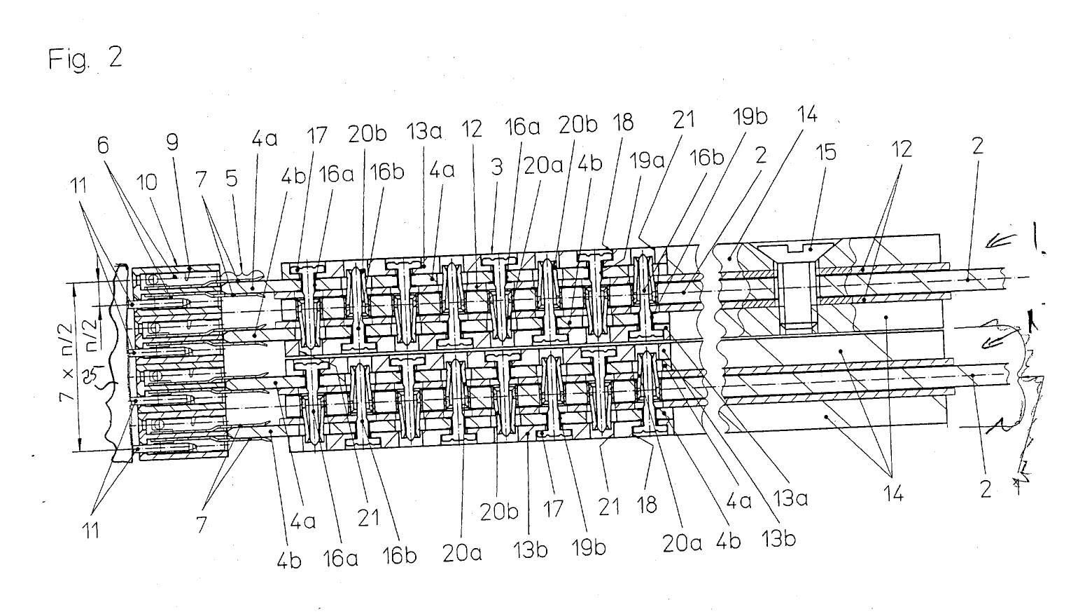

FIGS. 1 and 2 show the principal parts of two identical testing units 1 each having a main printed-circuit board 2 which in its right-hand end (cut off in the view) carries the electronics of the respective evaluating circuit and which has a left-hand contact region 3 with a pair of opposite faces juxtaposed with respective side printed-circuit plates 4a and 4b. Each of these plates 4a and 4b has an end projecting past the edge of the respective board 2 and forming there a solder region 5 for spring contacts 6 engaging traces on both faces of the boards 4a and 4b. Each contact 6 has a spring leg 7 secured by solder 8 to the respective trace in the region 5 on the respective face of the board 4a or 4b and is seated in a housing 9 of a spring strip 10. The opposite edge of the spring strip 10 forms individual sockets for pins 11 of a test apparatus 25. The pins 11 are connected at their tops at an upper adapter plate 25 of a test apparatus in which a number of the test units 1 are set one next the other on edge, to which end the spring strip 10 opens upward. The pins 11 are connected on the other side of the adapter plate 25 to respective contacts intended to engage the face of the printed-circuit board being tested.

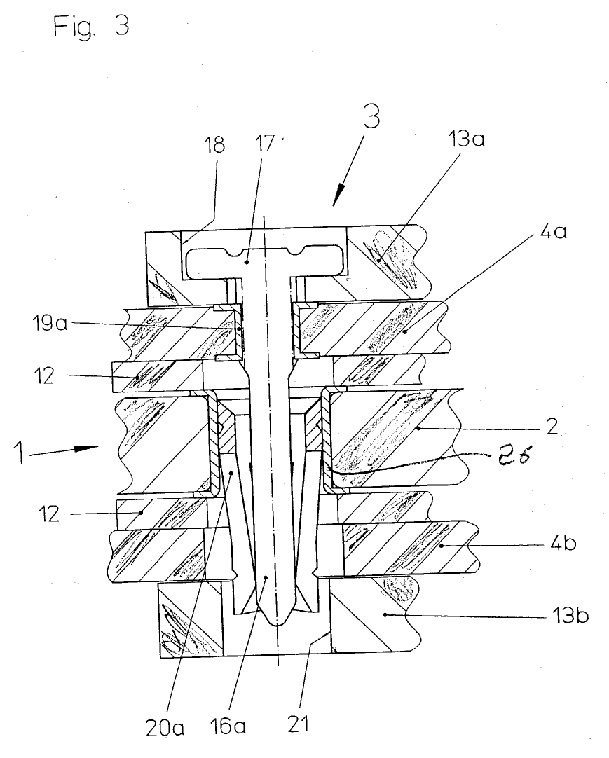

As also shown in FIG. 3, between each side board 4a and 4b and the respective face of the board 2 is an inner dielectric spacer plate 12 and thicker outer dielectric plates 13a and 13b bear against the outer faces of the side boards 4a and 4b. The contact region of the board 2 is formed with sixteen rows of eight through-plated contact holes 26 each holding a respective so-called holetite or socket contact 20a or 20b which are oppositely directed. The rows of contact holes 26 are set at a transverse spacing equal to n. The contact legs 7 are, however, set at a transverse spacing equal to n/2, and there are two boards 4a and 4b for each board 2, so that for each of the holes 26 in a row there is a respective contact leg 7. The boards 13a and 13b are unitary with the ends of mounting rails 14 that are secured to the boards 2 by screws 15.

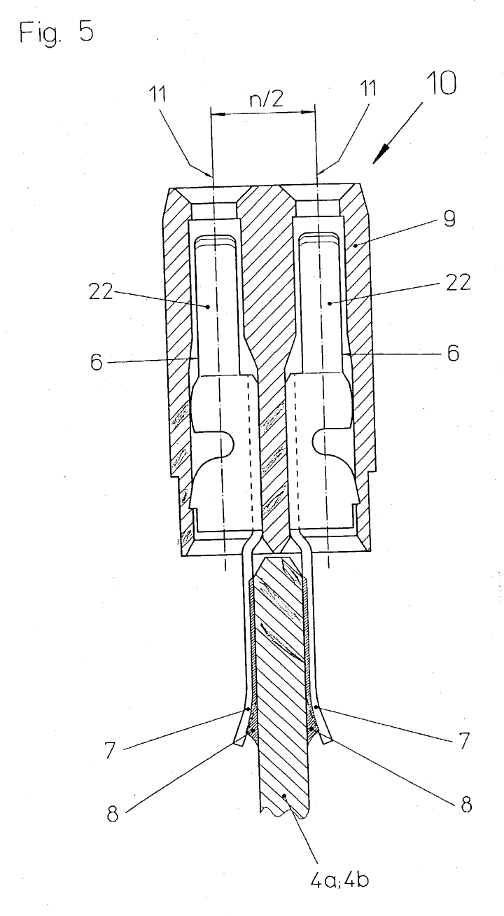

In accordance with the invention, the connection between the legs 7 and the holes 26 is made by conductive press-in contact pins 16a and 16b having heads set in counterbores 18 of the respective outer spacer plates 13a and 13b and shafts engaged in the respective socket contacts 20a and 20b. Each of the plates 4a and 4b is formed opposite the counterbores 18 of the other plate with a hole 21 in which the end of the other board's pin 16a or 16b and socket contact 20a or 20b can engage with spacing, so as not to contact the other board 4a or 4b. Here the spacing n is equal to 2.54 mm so that the pins 11 can be spaced at 1.27 mm. A single spring strip 10 can therefore connect to 128 pins 11. The spacing of the pins 11 transverse to the plane of the respective board 2 is also equal to n/2 as shown in FIGS. 2 and 5.

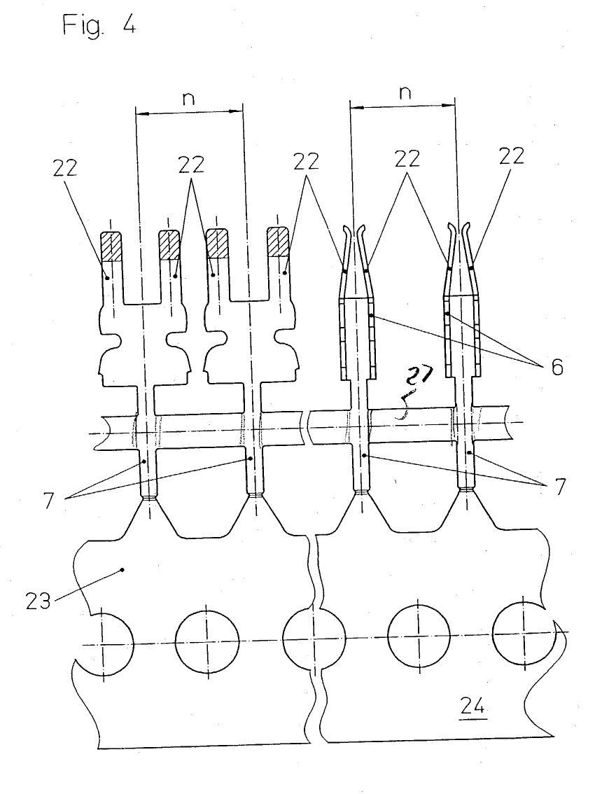

As shown in FIG. 4 the contacts 6 are stamped from a blank 23 with the legs 7 each unitary with a pair of legs 22 that initially are flat as shown on the left and then folded up through 90°. The contacts 6 are separated from the edge strip 24 and connecting webs 27 prior to use.

I claim:

1. An apparatus for testing a printed-circuit board, the apparatus comprising:
an array of closely spaced sensor pins formed by a plurality of contiguous zones each having a predetermined number of the sensor pins;
respective spring strips juxtaposed with the zones and each having the predetermined number of contacts each formed with a socket for a respective one of the pins of the respective zone;
respective main printed-circuit boards juxtaposed with the spring strips, each having oppositely directed first and second sides, and each having an end region formed with an array of the predetermined number of contact points;
respective first and second side boards flanking the first and second faces of each of the end regions and each having contact points each connected to a respective one of the spring-strip contacts; and
respective first and second arrays of press-in pins engaged through the respective first and second side boards with the contact points of the respective faces of the respective main boards.

2. The test apparatus defined in claim 1 wherein each array of press-in pins has half the predetermined number of press-in pins.

3. The test apparatus defined in claim 2 wherein the side-board contact points are arranged in rows set at a predetermined spacing equal to generally twice a spacing between adjacent sensor pins.

4. The test apparatus defined in claim 1, further comprising
respective outer insulating plates lying against outer faces of the side boards, the press-in pins having heads bearing on the outer insulating plates and projecting through the respective outer insulating plates.

5. The test apparatus defined in claim 4 wherein each outer insulating plate is formed with counterbores receiving the heads of the respective press-in pins.

6. The test apparatus defined in claim 4, further comprising
respective inner insulating plates between the side boards and the respective faces of the main boards, the press-in pins passing through the inner insulating plates.

7. The test apparatus defined in claim 4 wherein the outer insulating plates are connected to rails holding the respective main board.

9. The test apparatus defined in claim 1 wherein the first press-in pins are seated in the respective first side boards and are substantially out of contact with the respective second side boards and the second press-in pins are seated in the respective second side boards and are substantially out of contact with the respective first side boards.

10. The test apparatus defined in claim 1 wherein the main-board contact points are formed as throughgoing conductively lined holes.

11. The test apparatus defined in claim 1 wherein the side boards have conductive traces connecting the respective side-board contact points with the respective spring-strip contacts.

12. The test apparatus defined in claim 11 wherein the spring-strip contacts are soldered to the respective traces.

13. The test apparatus defined in claim 1 wherein the spring-strip contacts are stamped of sheet metal.
